(19) United States
(12) Patent Application Publication
(10) Pub. No.: US 2026/0323849 A1
(43) Pub. Date: Oct. 15, 2026

(54) DISPLAY DEVICE, METHOD FOR FABRICATING DISPLAY DEVICE AND ELECTRONIC DEVICE INCLUDING DISPLAY DEVICE

(71) Applicant: Samsung Display Co., LTD., Yongin-si (KR)

(72) Inventors: Young Je CHO, Yongin-si (KR); Sang Hyun HAN, Yongin-si (KR)

(21) Appl. No.: 19/411,838

(22) Filed: Dec. 8, 2025

(30) Foreign Application Priority Data
Apr. 10, 2025 (KR) 10-2025-0047030

(51) Int. Cl. H05K 5/02; H05K 5/03

(52) U.S. Cl. CPC H05K 5/0217; H05K 5/03

(57) ABSTRACT

A display device includes a display module, and a module support member placed under the display module, where the module support member includes a first support layer, a second support layer placed under the first support layer, and a plurality of supports arranged inside one of the first support layer and the second support layer.

This application claims priority to Korean Patent Application No. 10-2025-0047030, filed on Apr. 10, 2025, and all the benefits accruing therefrom under 35 U.S.C. §119, the content of which in its entirety is herein incorporated by reference.

### BACKGROUND

### 1. Field of the Disclosure

The present disclosure relates to a display device, a method for fabricating a display device, and an electronic device including a display device.

### 2. Description of the Related Art

Multimedia devices such as televisions, mobile phones, tablet computers, laptop computers and game consoles include display devices for providing images to users. Recently, a variety of types of display devices are under development as the technology of display devices evolves. For example, a variety of flexible display devices are being developed, which can be transformed into a curved shape, can be folded, or can be rolled. Flexible display devices are easy to carry and can improve user convenience.

Among these, rollable display devices have the advantage in that they are easy to carry even with a large display area, and thus a lot of research on rollable display devices is ongoing. Rollable display devices may be stored by rolling up the display module around the roll frame or the like, and the display module may be unfolded in use.

### SUMMARY

Aspects of the present disclosure provide a display device that can prevent silicone oil from being released out of a module support member, a method for fabricating a display device, and an electronic device including a display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a display module, and a module support member placed under the display module, where the module support member includes a first support layer, a second support layer placed under the first support layer, and a plurality of supports arranged inside one of the first support layer and the second support layer.

The first support layer may have a lower modulus than the second support layer.

The first support layer may have a lower viscosity than the second support layer.

The supports may be arranged inside the first support layer, and a thickness of the first support layer may be larger than a thickness of the second support layer.

The thickness of the first support layer may be at least three times the thickness of the second support layer, and a thickness of the supports may be at least twice the thickness of the second support layer.

Lower surfaces of the supports may be in contact with an upper surface of the second support layer.

The supports may be arranged inside the second support layer, and a thickness of the first support layer may be smaller than a thickness of the second support layer.

The thickness of the second support layer may be at least three times the thickness of the first support layer, and a thickness of the supports may be at least twice the thickness of the first support layer.

Upper surfaces of the supports may be in contact with a lower surface of the first support layer.

The module support member may further include a protective film located on the first support layer, and a cover layer located on under the second support layer, and the protective film may be in contact with the display module.

According to an aspect of the present disclosure, a method for fabricating a display device includes forming one of a first support layer and a second support layer, arranging a plurality of supports on the one of the first support layer and the second support layer, and forming the other of the first support layer and the second support layer on the one of the first support layer and the second support layer such that the plurality of supports is arranged inside the other of the first support layer and the second support layer.

The forming of the one of the first support layer and the second support layer may include forming the second support layer, and the forming of the second support layer may include applying a second resin into a first cavity of a first jig and then thermally curing the second resin.

The arranging of the plurality of supports on the one of the first support layer and the second support layer may include arranging the plurality of supports on the second support layer.

The forming of the other of the first support layer and the second support layer on the one of the first support layer and the second support layer such that the plurality of supports is arranged inside the other of the first support layer and the second support layer may include forming the first support layer on the second support layer such that the plurality of supports is arranged inside the first support layer, and the forming of the first support layer on the second support layer such that the plurality of supports is arranged inside the first support layer may include placing a second jig having a protective film therein on the first jig, injecting a first resin into a second cavity of the second jig, and thermally curing the first resin.

The forming of the one of the first support layer and the second support layer may include forming the first support layer, and the forming of the first support layer may include placing a protective film on a first jig, placing a first block on an edge of the protective film to form a first cavity, and applying a first resin into the first cavity and then thermally curing the first resin.

The arranging of the plurality of supports on the one of the first support layer and the second support layer may include arranging the plurality of supports on the first support layer.

The forming of the other of the first support layer and the second support layer on the one of the first support layer and the second support layer such that the plurality of supports is arranged inside the other of the first support layer and the second support layer may include forming the second support layer on the first support layer such that the plurality of supports is arranged inside the second support layer, and the forming of the second support layer on the first support layer so that the plurality of supports is arranged inside the second support layer may include placing a second block on the first block to form a second cavity, applying a second resin into the second cavity, and thermally curing the second resin.

The method for fabricating a display device may further include placing a cover layer on the second support layer.

According to an aspect of the present disclosure, an electronic device includes a display module, and a module support member placed under the display module, where the module support member includes a first support layer, a second support layer placed under the first support layer, and a plurality of supports arranged inside one of the first support layer and the second support layer.

The electronic device may further include at least one of a processor, a memory in which data on at least one of the display module and the processor is stored, and a power module for supplying power to at least one of the display module, the processor and the memory.

According to an embodiment of the present disclosure, a plurality of support layers having different moduli or viscosities is formed inside a module support member in a display device, so that it is possible to prevent silicone oil from being released out of the module support member.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view of a display device according to an embodiment of the present disclosure.

FIG. 2 is a side view showing a part of the display device of FIG. 1 when it is rolled.

FIG. 3 is a cross-sectional view taken along line A – A' of FIG. 1.

FIG. 4 is a cross-sectional view showing the display panel of FIG. 3.

FIG. 5 is a view schematically showing the module support member of the display device according to the first embodiment of the present disclosure.

FIG. 6 is a view schematically showing the module support member of the display device according to the second embodiment of the present disclosure.

FIGS. 7 and 8 are views showing that the second support layer of the module support member is formed in the method for fabricating the display device according to the first embodiment of the present disclosure.

FIG. 9 is a view showing that a plurality of supports is arranged on the second support layer in the method for fabricating the display device according to the first embodiment of the present disclosure.

FIGS. 10 and 11 are views showing that the first support layer is formed in the method for fabricating the display device according to the first embodiment of the present disclosure.

FIG. 12 is a view showing that a cover layer is coupled with the second support layer in the method for fabricating the display device according to the first embodiment of the present disclosure.

FIGS. 13 and 14 are views showing that the first support layer is formed in the method for fabricating the display device according to the second embodiment of the present disclosure.

FIGS. 15 and 16 are views showing that a plurality of supports is arranged on the first support layer, and a second support layer is formed in the method for fabricating the display device according to the second embodiment of the present disclosure.

FIG. 17 is a view showing that a cover layer is coupled with the second support layer in the method for fabricating the display device according to the second embodiment of the present disclosure.

FIG. 18 is a block diagram of an electronic device according to an embodiment of the present disclosure.

FIG. 19 is a view showing electronic devices according to a variety of embodiments of the present disclosure.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as “first”, “second”, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, example embodiments of the present disclosure will be described in detail with reference to the accompanying drawings.

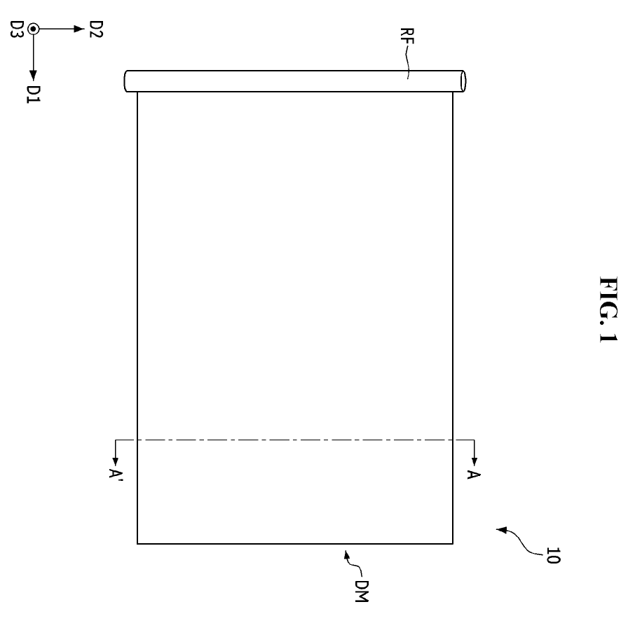

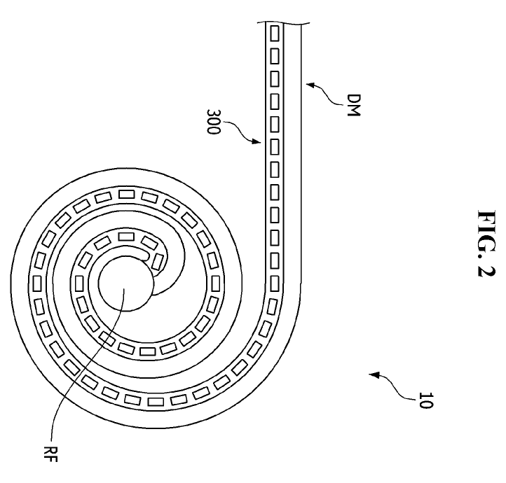

FIG. 1 is a plan view of a display device according to an embodiment of the present disclosure. FIG. 2 is a side view showing the display device of FIG. 1 when it is rolled.

As used herein, a display device 10 according to an example embodiment of the present disclosure is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things. Alternatively, the display device 10 may be used as a display screen applied to the center fascia of a vehicle.

The display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro light-emitting display device using micro light-emitting diodes (LED). In the following description, an organic light-emitting display device is described as an example of the display device 10. It is, however, to be understood that the present disclosure is not limited thereto.

The first direction D1 may refer to a direction parallel to a side of the display device 1, for example, the horizontal direction of the display device 10 when viewed from the top. A second direction D2 may refer to a direction parallel to another side of the display device 10 that meet the side of the display device 10, for example, the vertical direction of the display device 10 when viewed from the top. A third direction D3 may refer to the thickness direction of the display device 10.

The display device 10 may have a quadrangular shape, such as a rectangular shape when viewed from the top. For example, the display device 10 may have a rectangular shape having longer sides in the first direction D1 and shorter sides in the second direction D2 when viewed from the top. The corners where the longer sides in the first direction D1 meet the shorter sides in the second direction D2 may be rounded with a predetermined curvature or may be a right angle. The shape of the display device 10 when viewed from the top is not limited to a rectangular shape but may be formed in another polygonal shape, a circular shape, or an elliptical shape.

The display device 10 may include a display area and a non-display area. The shape of the display area may follow the shape of the display device 10 when viewed from the top. For example, when the display device 10 has a rectangular shape when viewed from the top, the display area may also have a rectangular shape when viewed from the top.

The display area may include a plurality of pixels to display images. The non-display area may not include pixels and thus may not display images. The non-display area may be located around the display area. The non-display area may surround the display area, but the embodiments of the present disclosure are not limited thereto. The display area may be partially surrounded by the non-display area.

Referring to FIGS. 1 and 2, the display device 10 according to a first embodiment of the present disclosure may be a rollable display device. The display device 10 may include a roll frame RF, a display module DM, and a module support member 300.

The roll frame RF may be formed into a rod shape having a circular cross-section. The roll frame RF may be extended in the second direction D2 and may be rotated clockwise or counterclockwise in the first direction D1. By the rotation of the roll frame RF, the display module DM connected to the roll frame RF may be unfolded or rolled around the roll frame RF.

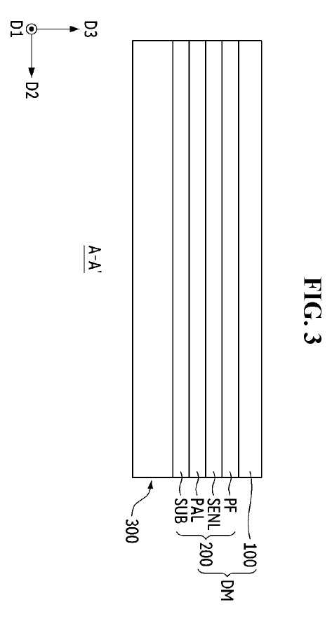

FIG. 3 is a cross-sectional view taken along line A – A' of FIG. 1.

Referring to FIG. 3, the display module DM may include a cover window 100 and a display panel 200.

The cover window 100 may include a material with high light transmittance. The cover window 100 may include a polymer resin such as polyimide or glass. The cover window 100 may be attached onto a polarizing film PF of the display panel 200 by an adhesive member such as an optically clear adhesive (OCA) film.

The display panel 200 may be placed under the cover window 100. The display panel 200 may have a rectangular shape having longer sides in the first direction D1 and shorter sides in the second direction D2 when viewed from the top. In the display panel 200, the corners where the longer sides in the first direction D1 meet the shorter sides in the second direction D2 may be formed at a right angle or may be rounded with a predetermined curvature. The display panel 200 may have a quadrangular shape other than a rectangle, a polygonal shape other than a quadrangular shape, a circular shape, an oval shape, or an irregular shape when viewed from the top.

The display panel 200 may include a display area where a plurality of emission areas that emits light is arranged, and a non-display area disposed around the display area. The non-display area may surround the display area. A plurality of display pads may be disposed in the non-display area at one edge of the display panel 200.

The display panel 200 may include a substrate SUB, a display unit PAL, a sensor unit SENL and a polarizing film PF.

The substrate SUB may be made of an insulating material such as glass, quartz and a polymer resin. The substrate SUB may be a rigid substrate or a flexible substrate that can be bent, folded, rolled, and so on.

The display unit PAL may be placed on the substrate SUB. The display unit PAL may be a layer including a plurality of emission areas that emit light. The display unit PAL may include a buffer film, a thin-film transistor layer on which thin-film transistors are disposed, a light-emitting element layer that emits light, and an encapsulating layer for encapsulating the light-emitting element layer.

The sensor unit SENL may be placed on the display unit PAL. The sensor unit SENL may include sensor electrodes and may sense whether there is a user's touch.

The polarizing film PF may be placed on the sensor unit SENL. The polarizing film PF can prevent the deterioration of image visibility of the display panel 200 due to reflection of external light. The polarizing film may include a linear polarizer and a retardation film such as a λ/4 (quarter-wave) plate. The phase retardation film may be placed on the sensor unit SENL, and the linear polarizer may be placed on the phase retardation film. The cover window 100 may be placed on the polarizing film PF.

The module support member 300 may be located under the substrate SUB. The module support member 300 may be attached to the lower surface of the substrate SUB by an adhesive layer (not shown). The adhesive layer (not shown) may be a pressure-sensitive adhesive (PSA).

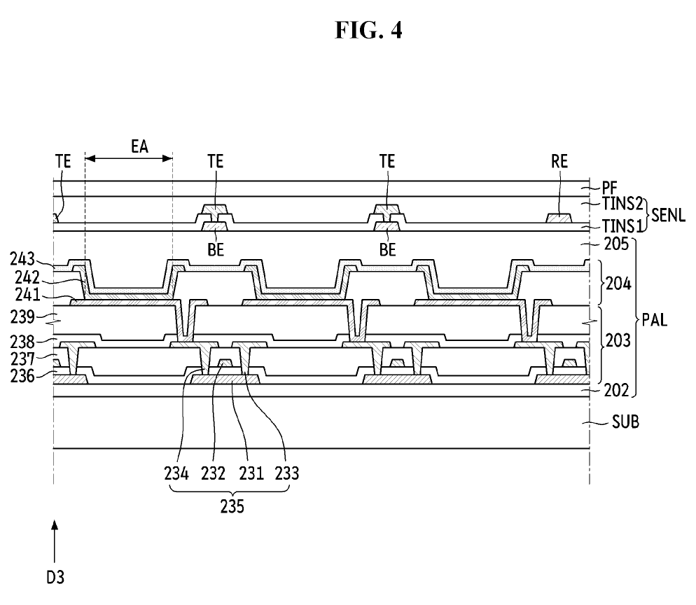

FIG. 4 is a cross-sectional view showing the display panel of FIG. 3.

Referring to FIG. 4, the display unit PAL may include a buffer layer 202, a thin-film transistor layer 203, a light-emitting element layer 204, and an encapsulation layer 205.

The buffer layer 202 may be formed on the substrate SUB. The buffer layer 202 may be formed on the substrate SUB to protect the thin-film transistors 235 and the light-emitting elements from moisture permeating through the substrate SUB that is susceptible to moisture permeation. The buffer layer 202 may be formed of a plurality of inorganic layers stacked on one another alternately. For example, the buffer layer 202 may be made up of multiple layers in which one or more inorganic layer of a silicon oxide layer (SiOx), a silicon nitride layer (SiNx) and SiON are stacked on one another alternately. The buffer layer 202 may be eliminated.

The thin-film transistor layer 203 is formed on the buffer layer 202. The thin-film transistor layer 203 includes thin-film transistors 235, a gate insulator 236, an interlayer dielectric layer 237, a protective layer 238, and an organic layer 239.

Each of the thin-film transistor 235 includes an active layer 231, a gate electrode 232, a source electrode 233, and a drain electrode 234. In FIG. 4, the thin-film transistors 235 are implemented as top-gate transistors in which the gate electrode 232 is located above the active layer 231. It is, however, to be understood that the present disclosure is not limited thereto. That is to say, the thin-film transistors 235 may be implemented as bottom-gate transistors in which the gate electrode 232 is located below the active layer 231, or as double-gate transistors in which the gate electrodes 232 are disposed above and below the active layer 231.

The active layer 231 is formed on the buffer layer 202. The active layer 231 may be formed of a silicon-based semiconductor material or an oxide-based semiconductor material. For example, the active layer 231 may be formed of polycrystalline silicon, amorphous silicon, or an oxide semiconductor. A light-blocking layer for blocking external light incident on the active layer 231 may be formed between the buffer layer 202 and the active layer 231.

The gate insulator 236 may be formed on the active layer 231. The gate insulator 236 may be formed of an inorganic layer, for example, a silicon oxide layer (SiOx), a silicon nitride layer (SiNx), or a multilayer thereof.

The gate electrode 232 may be formed on the gate insulator 236. The gate electrode 232 and the gate lines may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The interlayer dielectric layer 237 may be formed over the gate electrodes 232 and the gate lines. The interlayer dielectric layer 237 may be formed of an inorganic layer, for example, a silicon oxide layer (SiOx), a silicon nitride layer (SiNx), or a multilayer thereof.

The source electrode 233 and the drain electrode 234 may be formed on the interlayer dielectric layer 237. Each of the source electrode 233 and the drain electrode 234 may be connected to the active layer 231 through a contact hole penetrating through the gate insulator 236 and the interlayer dielectric layer 237. The source electrode 233 and the drain electrode 234 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The protective layer 238 may be formed on the source electrode 233 and the drain electrode 234 in order to insulate the thin-film transistors 235. The protective layer 238 may be formed of an inorganic layer, e.g., a silicon oxide layer (SiOx), a silicon nitride layer (SiNx), or a multilayer thereof.

The organic layer 239 may be formed on the protective layer 238 to provide a flat surface over the thin-film transistors 235 having difference levels. The organic layer 239 may be implemented as an organic film such as an acryl resin, an epoxy resin, a phenolic resin, a polyamide resin and a polyimide resin.

The light-emitting element layer 204 is formed on the thin-film transistor layer 203. The light-emitting element layer 204 includes the light-emitting elements and a bank.

The light-emitting elements and the bank are formed on the organic layer 239. An organic light-emitting device including an anode electrode 241, emissive layers 242 and a cathode electrode 243 is employed as an example of the light-emitting elements.

The anode electrode 241 may be formed on the organic layer 239. The anode electrode 241 may be connected to the source electrode 233 of the thin-film transistor 235 via a contact hole penetrating through the protective layer 238 and the organic layer 239.

The bank may be formed to cover the edge of the anode electrode 241 on the organic layer 239 to define the emission areas EA of the pixels. That is to say, the bank may define the emission areas EA of the pixels. In each of the pixels, the anode electrode 241, the emissive layer 242 and the cathode electrode 243 are sequentially stacked on one another so that holes from the anode electrode 241 and electrons from the cathode electrode 243 combine in the emissive layer 242 to emit light.

The emissive layers 242 are formed on the anode electrode 241 and the bank. The emissive layers 242 may be organic emissive layers. The emissive layers 242 may emit one of red light, green light, and blue light. Alternatively, the emissive layer 242 may be a white emissive layer that emits white light. In such case, the red emissive layer, the green emissive layer and the blue emissive layer may be stacked on one another or may be formed commonly across the pixels as a common layer. In such case, the display panel 200 may further include additional color filters for representing red, green and blue colors.

The emissive layer 242 may include a hole transporting layer, a light-emitting layer, and an electron transporting layer. In addition, the emissive layer 242 may be formed in a tandem structure of two or more stacks, in which case a charge generating layer may be formed between the stacks.

The cathode electrode 243 is formed on the emissive layer 242. The cathode electrode 243 may be formed to cover the emissive layer 242. The cathode electrode 243 may be a common layer formed across the pixels.

When the light-emitting element layer 204 is of a top-emission type in which light exits toward the upper side, the anode electrode 241 may be made of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). The APC alloy is an alloy of silver (Ag), palladium (Pd) and copper (Cu). The cathode electrode 243 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the cathode electrode 243 is formed of a translucent conductive material, the light extraction efficiency can be increased by using microcavities.

When the light-emitting element layer 204 is of a bottom-emission type in which light exits toward the lower side, the anode electrode 241 may be formed of a transparent conductive material (TCP) such as ITO and IZO that can transmit light, or a semi-transmissive conductive material such as magnesium (Mg), silver (Ag) and an alloy of magnesium (Mg) and silver (Ag). The cathode electrode 243 may be made of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). When the anode electrode 241 is formed of a semi-transmissive conductive material, the light extraction efficiency can be increased by using microcavities.

The encapsulation layer 205 is formed on the light-emitting element layer 204. The encapsulation layer 205 serves to prevent permeation of oxygen or moisture into the emissive layer 242 and the cathode electrode 243. To this end, the encapsulation layer 205 may include at least one inorganic film. The inorganic film may be made of silicon nitride, aluminum nitride, zirconium nitride, titanium nitride, hafnium nitride, tantalum nitride, silicon oxide, aluminum oxide, or titanium oxide. In addition, the encapsulation layer 205 may further include at least one organic film. The organic film may have a sufficient thickness to prevent particles from permeating into the encapsulation layer 205 and entering the emissive layer 242 and the cathode electrode 243. The organic film may include one of epoxy, acrylate and urethane acrylate.

The sensor unit SENL may be formed on the encapsulation layer 205. When the sensor unit SENL is formed directly on the encapsulation layer 205, the thickness of the display device 10 can be reduced, compared with a display device in which a separate touch panel is attached on the encapsulation layer 205.

The sensor unit SENL may include sensor electrodes for sensing a user's touch by capacitive sensing, and touch lines for connecting the pads with the sensor electrodes. For example, the sensor unit SENL can sense a user's touch by self-capacitance sensing or mutual capacitance sensing. In the example shown in FIG. 4, the sensor unit SENL is made up of two layers including driving electrodes TE, sensing electrodes RE and bridge electrodes BE connecting between the driving electrodes TE for mutual capacitance sensing.

The bridge electrodes BE may be formed on the encapsulation layer 205. The bridge electrodes BE may be made up of, but is not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). For example, the bridge electrodes BE may be made up of a single layer of molybdenum (Mo), titanium (Ti), copper (Cu), aluminum (Al) or ITO.

A first sensing insulating layer TINS1 is formed over the bridge electrodes BE. The first sensing insulating layer TINS1 may be formed of an inorganic film, for example, a silicon nitride layer, a silicon oxynitride layer, a silicon oxide layer, a titanium oxide layer, or an aluminum oxide layer.

The driving electrodes TE and the sensing electrodes RE may be formed on the first sensing insulating layer TINS1. The driving electrode TE and the sensing electrode RE may be formed as, but is not limited to, a stack structure of aluminum and titanium (Ti / Al / Ti), a stack structure of aluminum and ITO (ITO / Al / ITO), an APC alloy and a stack structure of APC alloy and ITO (ITO / APC / ITO). For example, the driving electrodes TE and the sensing electrodes RE may be made up of a single layer of molybdenum (Mo), titanium (Ti), copper (Cu), aluminum (Al) or ITO.

Contact holes may be formed in the first sensing insulating layer TINS1 which penetrate the first sensing insulating layer TINS1 to expose the bridge electrodes BE. The driving electrodes TE may be connected to the bridge electrodes BE through the contact holes.

A second sensing insulating layer TINS2 is formed over the driving electrodes TE and the sensing electrodes RE. The second sensing insulating layer TINS2 may provide a flat surface over the driving electrodes TE, the sensing electrodes RE and the bridge electrodes BE which have different heights. The second sensing insulating layer TINS2 may be formed of an organic layer such as an acryl resin, an epoxy resin, a phenolic resin, a polyamide resin and a polyimide resin.

The bridge electrodes BE connecting between the adjacent driving electrodes TE may be located on the encapsulation layer 205, and the driving electrodes TE and the sensing electrodes RE may be located on the first sensing insulating layer TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The polarizing film PF may be placed on the second sensing insulating layer TINS2 and can prevent the deterioration of image visibility of the display panel 200 due to reflection of external light.

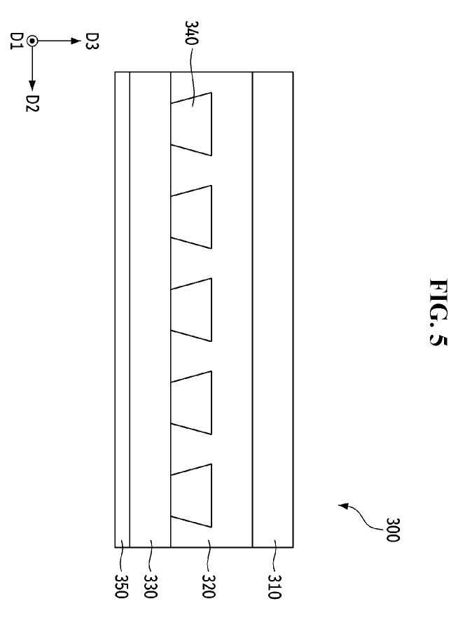

FIG. 5 is a view schematically showing the module support member of the display device according to the first embodiment of the present disclosure.

Referring to FIG. 5, the module support member 300 may include a protective film 310, a first support layer 320, a second support layer 330, a plurality of supports 340, and a cover layer 350.

The protective film 310 may be placed under the display module DM. For example, the protective film 310 may be placed under the substrate SUB of the display panel 200. The protective film 310 may be provided as a film made of a transparent material having a thickness. For example, the protective film 310 may include one or more of TPU, PET, PI, and PEBA (polyether block amide) films. The protective film 310 may have a modulus equal to the modulus of the first support layer 320. The protective film 310 may attach the module support member 300 to the substrate SUB of the display panel 200.

The first support layer 320 may be placed under the protective film 310. The first support layer 320 may include a silicone resin. For example, the first support layer 320 may include at least one of silicone and urethane acrylate. The first support layer 320 may have a lower modulus than the second support layer 330. For example, the first support layer 320 may have a modulus of 0.5 megapascals (MPa) or less. For example, the first support layer 320 may be formed to have the modulus of 0.2 MPa.

The first support layer 320 may have a lower viscosity than the second support layer 330. For example, the first support layer 320 may have a viscosity of 500 millipascal seconds (mPa∙s) to 1,500 mPa∙s. For example, the first support layer 320 may be formed to have the viscosity of 1,000 mPa∙s.

The thickness of the first support layer 320 may be larger than the thickness of the second support layer 330. For example, the thickness of the first support layer 320 may be three times or more the thickness of the second support layer 330. For example, the thickness of the first support layer 320 may be 600 micrometers (μm).

The second support layer 330 may be placed under the first support layer 320. The second support layer 330 may include a silicone resin. For example, the second support layer 330 may include at least one of silicone and urethane acrylate. The second support layer 330 may have a higher modulus than the first support layer 320. For example, the second support layer 330 may have a modulus that is greater than 0.5 MPa and equal to or less than 5 MPa. For example, the second support layer 330 may be formed to have the modulus of 2 MPa.

The second support layer 330 may have a higher viscosity than the first support layer 320. For example, the second support layer 330 may have a viscosity of 30,000 mPa∙s to 50,000 mPa∙s. For example, the second support layer 330 may be formed to have the viscosity of 40,000 mPa∙s. Since the second support layer 330 has a higher viscosity than the first support layer 320, it is possible to prevent the silicone oil component generated in the first support layer 320 from leaking down through the second support layer 330.

The thickness of the second support layer 330 may be smaller than the thickness of the first support layer 320. For example, the thickness of the second support layer 330 may be one-third or less of the thickness of the first support layer 320. For example, the thickness of the second support layer 330 may be 200 μm.

The plurality of supports 340 may be arranged inside the first support layer 320. The plurality of supports 340 may be arranged spaced apart from each other along the second direction D2 inside the first support layer 320. The thickness of the plurality of supports 340 may be at least twice the thickness of the second support layer 330. For example, the thickness of the plurality of supports 340 may be 400 μm.

The plurality of supports 340 may be in contact with the second support layer 330. For example, the lower surfaces of the plurality of supports 340 may be in contact with the upper surface of the second support layer 330.

The plurality of supports 340 may include one or more of SUS, Al-alloy, Ti-alloy, CFRG, and GFRP (glass-fiber).

Although not shown in the drawings, the plurality of supports 340 may be arranged between the first support layer 320 and the second support layer 330.

The cover layer 350 may be placed under the second support layer 330. Since the second support layer 330 includes a silicone resin, the surface of the second support layer 330 is sticky even after the silicone resin has been cured. The cover layer 350 may be placed under the second support layer 330 to cover the sticky surface of the second support layer 330. The cover layer 350 may be provided as a film made of a transparent material having a thickness. Since the cover layer 350 is to cover the sticky surface of the second support layer 330, it may be formed by coating a silicone slip agent under the second support layer 330 instead of in a film. The cover layer 350 may include one or more of an AF coating film, a silicone slip agent, and a silicone textile.

Hereinafter, a display device 10 according to a second embodiment of the present disclosure will be described with reference to the accompanying drawings.

The display device 10 according to the second embodiment of the present disclosure may include a roll frame RF, a display module DM, and a module support member 300. The roll frame RF and the display module DM are substantially identical to those of the first embodiment; and, therefore, the redundant descriptions will be omitted.

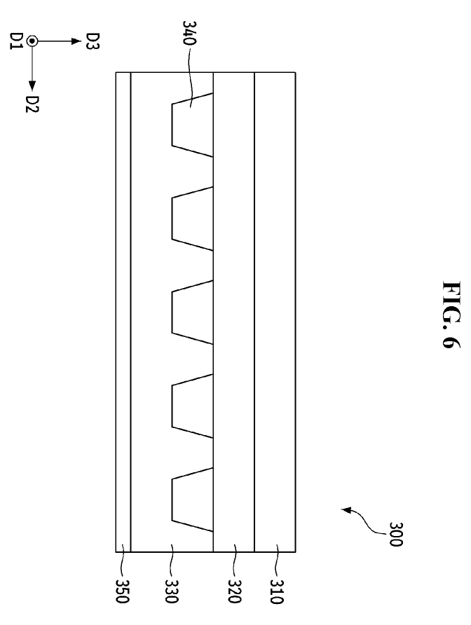

FIG. 6 is a view schematically showing the module support member of the display device according to the second embodiment of the present disclosure.

Referring to FIG. 6, the module support member 300 may include a protective film 310, a first support layer 320, a second support layer 330, a plurality of supports 340, and a cover layer 350.

The protective film 310 may be placed under the display module DM. For example, the protective film 310 may be placed under the substrate SUB of the display panel 200. The protective film 310 may be provided as a film made of a transparent material having a thickness. For example, the protective film 310 may include one or more of TPU, PET, PI, and PEBA (polyether block amide) films. The protective film 310 may have a modulus equal to the modulus of the first support layer 320. The protective film 310 may attach the module support member 300 to the substrate SUB of the display panel 200.

The first support layer 320 may be placed under the protective film 310. The first support layer 320 may include a silicone resin. For example, the first support layer 320 may include at least one of silicone and urethane acrylate. The first support layer 320 may have a lower modulus than the second support layer 330. For example, the first support layer 320 may be formed to have the modulus of 0.2 MPa.

The first support layer 320 may have a lower viscosity than the second support layer 330. For example, the first support layer 320 may have a viscosity of 500 mPa∙s to 1,500 mPa∙s. For example, the first support layer 320 may be formed to have the viscosity of 1,000 mPa∙s.

The thickness of the first support layer 320 may be smaller than the thickness of the second support layer 330. For example, the thickness of the first support layer 320 may be one-third or less of the thickness of the second support layer 330. For example, the thickness of the first support layer 320 may be 200 μm.

The second support layer 330 may be placed under the first support layer 320. The second support layer 330 may include a silicone resin. For example, the second support layer 330 may include at least one of silicone and urethane acrylate. The second support layer 330 may have a higher modulus than the first support layer 320. For example, the second support layer 330 may have a modulus that is greater than 0.5 MPa and equal to or less than 5 MPa. For example, the second support layer 330 may be formed to have the modulus of 2 MPa.

The second support layer 330 may have a higher viscosity than the first support layer 320. For example, the second support layer 330 may have a viscosity of 30,000 mPa∙s to 50,000 mPa∙s. For example, the second support layer 330 may be formed to have the viscosity of 40,000 mPa∙s. Since the second support layer 330 has a higher viscosity than the first support layer 320, it is possible to prevent the silicone oil component generated in the first support layer 320 from leaking down through the second support layer 330.

The thickness of the second support layer 330 may be larger than the thickness of the first support layer 320. For example, the thickness of the second support layer 330 may be three times or more the thickness of the first support layer 320. For example, the thickness of the second support layer 330 may be 600 μm.

The plurality of supports 340 may be arranged inside the second support layer 330. The plurality of supports 340 may be arranged spaced apart from each other along the second direction D2 inside the second support layer 330. The thickness of the plurality of supports 340 may be at least twice the thickness of the first support layer 320. For example, the thickness of the plurality of supports 340 may be 400 μm.

The plurality of supports 340 may be in contact with the first support layer 320. For example, the upper surfaces of the plurality of supports 340 may be in contact with the lower surface of the second support layer 330.

The plurality of supports 340 may include one or more of SUS, Al-alloy, Ti-alloy, CFRG, and GFRP (glass-fiber).

Although not shown in the drawings, the plurality of supports 340 may be arranged between the first support layer 320 and the second support layer 330.

The cover layer 350 may be placed under the second support layer 330. Since the second support layer 330 includes a silicone resin, the surface of the second support layer 330 is sticky even after the silicone resin has been cured. The cover layer 350 may be placed under the second support layer 330 to cover the sticky surface of the second support layer 330. The cover layer 350 may be provided as a film made of a transparent material having a thickness. Since the cover layer 350 is to cover the sticky surface of the second support layer 330, it may be formed by coating a silicone slip agent under the second support layer 330 instead of in a film. The cover layer 350 may include one or more of an AF coating film, a silicone slip agent, and a silicone textile.

Hereinafter, a method for fabricating a display device 10 according to the first embodiment of the present disclosure will be described with reference to the accompanying drawings.

The method for fabricating the display device 10 according to the first embodiment of the present disclosure may include: forming a second support layer 330; arranging a plurality of supports 340 on the second support layer 330; forming a first support layer 320 on the second support layer 330 so that the plurality of supports 340 is arranged inside the first support layer 320; and placing a cover layer 350 on the second support layer 330.

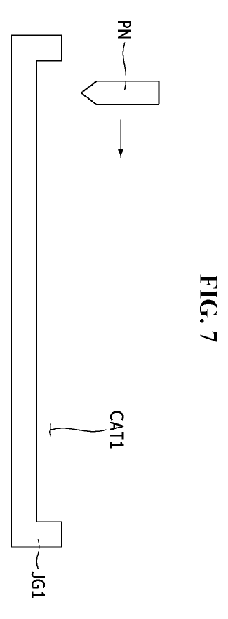

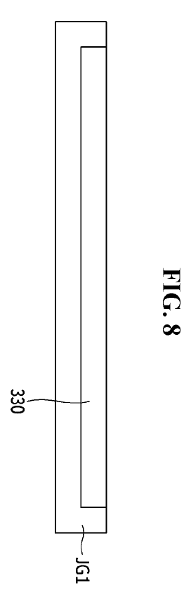

FIGS. 7 and 8 are views showing that the second support layer of the module support member is formed in the method for fabricating the display device according to the first embodiment of the present disclosure.

Referring to FIGS. 7 and 8, the forming the second support layer 330 may include applying a second resin into a first cavity CAT1 of a first jig JG1, and then thermally curing the second resin.

The first jig JG1 may be provided as a jig in which the first cavity CAT1 is opened so that the first cavity CAT1 is exposed upward. The second resin may be supplied to the first cavity CAT1 of the first jig JG1 through a supply nozzle PN. The supply nozzle PN may be moved horizontally above the first jig JG1 and may apply the second resin into the first cavity CAT1 of the first jig JG1. The second resin applied into the first cavity CAT1 of the first jig JG1 may be thermally cured at a temperature of 60°C to 80°C for 30 minutes to 1 hour. As the second resin is thermally cured as described above, the second support layer 330 may be formed.

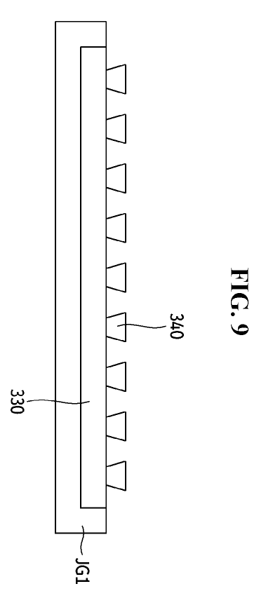

FIG. 9 is a view showing that a plurality of supports is arranged on the second support layer in the method for fabricating the display device according to the first embodiment of the present disclosure.

Referring to FIG. 9, the arranging the plurality of supports 340 on the second support layer 330 may include arranging the plurality of supports 340 on the second support layer 330 such that they are spaced apart from each other. The supports 340 may be equally spaced apart from each other.

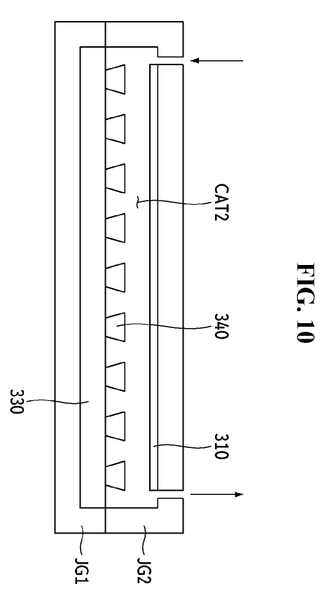

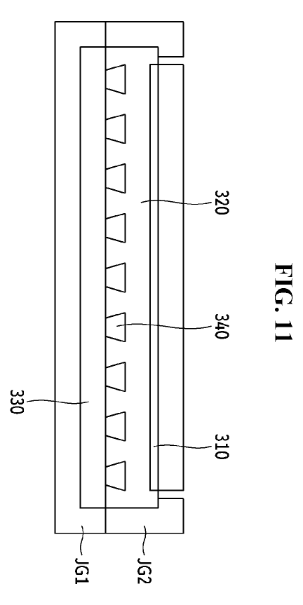

FIGS. 10 and 11 are views showing that the first support layer is formed in the method for fabricating the display device according to the first embodiment of the present disclosure.

Referring to FIGS. 10 and 11, the forming the first support layer 320 on the second support layer 330 so that the plurality of supports 340 is arranged inside the first support layer 320 may include: placing a second jig JG2 having a protective film 310 therein on the first jig JG1; injecting a first resin into a second cavity CAT2 of the second jig JG2; and thermally curing the first resin.

The second jig JG2 may be provided as a jig with an open bottom so that the second cavity CAT2 is exposed. An inlet and an outlet may be formed in the second jig JG2 to communicate with the second cavity CAT2.

The placing the second jig JG2 on the first jig JG1 may include placing the second jig JG2 on the first jig JG1 so that the second cavity CAT2 of the second jig JG2 is connected to the first cavity CAT1 of the first jig JG1. The protective film 310 may be placed on the upper side in the second cavity CAT2 of the second jig JG2.

The injecting the first resin into the second cavity CAT2 of the second jig JG2 may include injecting the first resin into the inlet of the second jig JG2. Once the second cavity CAT2 of the second jig JG2 is filled with the first resin injected into the second cavity CAT2, the first resin may be discharged through the outlet of the second jig JG2.

The thermally curing the first resin may include thermally curing the first resin injected into the second cavity CAT2 of the second jig JG2 at a temperature of 60°C to 80°C for 30 minutes to 1 hour. As the first resin is thermally cured as described above, the first support layer 320 may be formed.

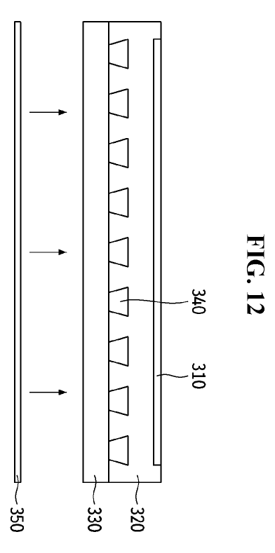

FIG. 12 is a view showing that a cover layer is coupled with the second support layer in the method for fabricating the display device according to the first embodiment of the present disclosure.

Referring to FIG. 12, the placing the cover layer 350 on the second support layer 330 may include attaching the cover layer 350 on the second support layer 330 such that it covers the second support layer 330. The cover layer 350 may be attached to the second support layer 330 detached from the first jig JG1. The cover layer 350 may be provided in the form of a film and attached to the second support layer 330, or may be formed by coating an AF coating film, a silicone slip agent, silicone textile or the like on the second support layer 330.

The module support member 300 thus fabricated may be cut into a constant size by laser cutting, etc.

Hereinafter, a method for fabricating a display device 10 according to the second embodiment of the present disclosure will be described with reference to the accompanying drawings.

The method for fabricating the display device 10 according to the second embodiment of the present disclosure may include: forming a first support layer 320; arranging a plurality of supports 340 on the first support layer 320; forming a second support layer 330 on the first support layer 320 so that the plurality of supports 340 is arranged inside the second support layer 330; and placing a cover layer 350 on the second support layer 330.

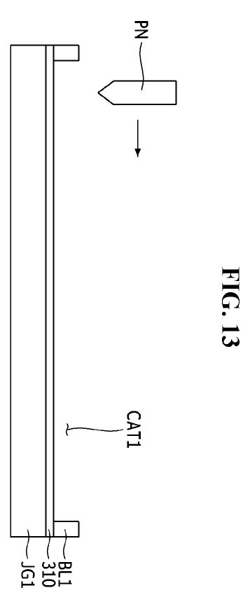

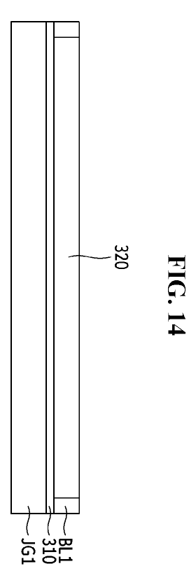

FIGS. 13 and 14 are views showing that the first support layer is formed in the method for fabricating the display device according to the second embodiment of the present disclosure.

Referring to FIGS. 13 and 14, the forming the first support layer 320 may include: placing a protective film 310 on a first jig JG1; placing a first block BL1 on an edge of the protective film 310 to form a first cavity CAT1; and applying a first resin into the first cavity CAT1 and then thermally curing the first resin.

The first jig JG1 may be provided as a plate-shaped jig having a thickness. The upper surface of the first jig JG1 may be flat for placing the protective film 310. In the placing the protective film 310 on the first jig JG1, the protective film 310 may be seated and arranged on the upper surface of the first jig JG1. The first jig JG1 may be made of a material containing at least one of glass, SUS, and Al, and Teflon or AF (anti-fingerprint or anti-fouling) may be coated on the surface of the first jig JG1.

The first block BL1 may be formed as a block that has a thickness equal to the thickness of the first support layer 320. The first block BL1 may be extended along the edge of the protective film 310, and accordingly a first cavity CAT1 may be formed on the protective film 310.

A first resin may be supplied into the first cavity CAT1 through a supply nozzle PN. The supply nozzle PN may be moved horizontally above the first jig JG1 and may apply the first resin into the first cavity CAT1.

The first resin applied into the first cavity CAT1 may be thermally cured at a temperature of 60°C to 80°C for 30 minutes to 1 hour. As the first resin is thermally cured as described above, a first support layer 320 may be formed.

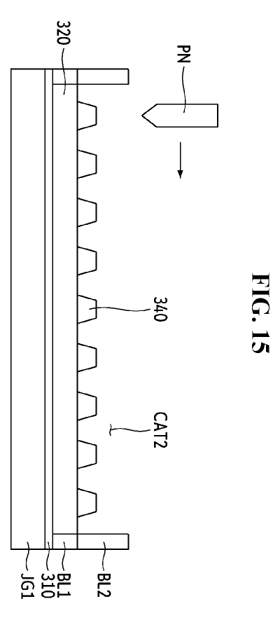

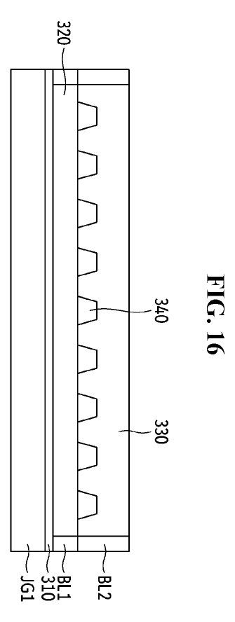

FIGS. 15 and 16 are views showing that a plurality of supports is arranged on the first support layer, and a second support layer is formed in the method for fabricating the display device according to the second embodiment of the present disclosure.

Referring to FIGS. 15 and 16, the arranging the plurality of supports 340 on the first support layer 320 may include arranging the plurality of supports 340 on the first support layer 320 such that they are spaced apart from each other. The supports 340 may be equally spaced apart from each other.

The forming the second support layer 330 on the first support layer 320 so that the plurality of supports 340 is arranged inside the second support layer 330 may include: placing a second block BL2 on the first block BL1 to form a second cavity CAT2; applying a second resin into the second cavity CAT2; and thermally curing the second resin.

The second block BL2 may be formed as a block that has a thickness equal to the thickness of the second support layer 330. The second block BL2 may be placed on the first block BL1 and extended along the first block BL1, and accordingly the second cavity CAT2 may be formed on the first support layer 320.

A second resin may be supplied into the second cavity CAT2 through a supply nozzle PN. The supply nozzle PN may be moved horizontally above the first support layer 320 and may apply the second resin into the second cavity CAT2.

The second resin applied into the second cavity CAT2 may be thermally cured at a temperature of 60°C to 80°C for 30 minutes to 2 hour. As the second resin is thermally cured as described above, a second support layer 330 may be formed.

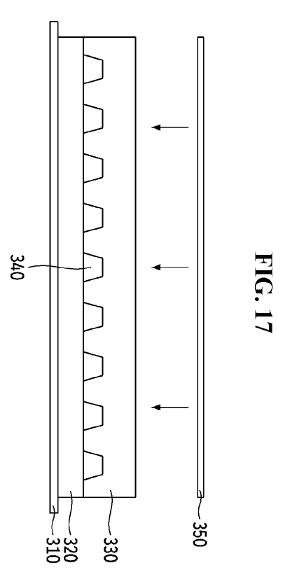

FIG. 17 is a view showing that a cover layer is coupled with the second support layer in the method for fabricating the display device according to the second embodiment of the present disclosure.

Referring to FIG. 17, the placing the cover layer 350 on the second support layer 330 may include attaching the cover layer 350 on the second support layer 330 such that it covers the second support layer 330. The cover layer 350 may be attached to the second support layer 330 detached from the first jig JG1.

The module support member 300 thus fabricated may be cut into a constant size by laser cutting, etc.

The display device according to the embodiment of the present disclosure may be applied to a variety of electronic devices. An electronic device according to an embodiment includes the display device described above, and may further include a module or device having additional features in addition to the display device.

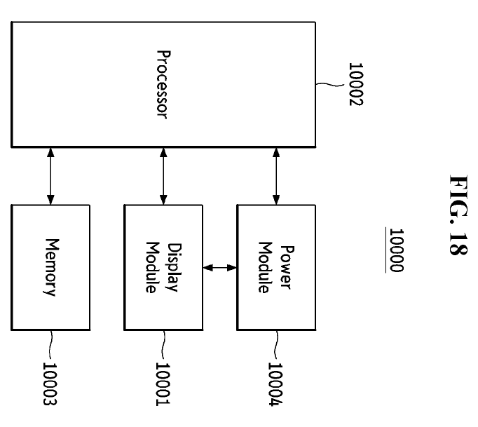

FIG. 18 is a block diagram of an electronic device according to an embodiment of the present disclosure.

Referring to FIG. 18, an electronic device 10000 according to an embodiment of the present disclosure may include a display module 10001, a processor 10002, a memory 10003, and a power module 10004.

The processor 10002 may include at least one of: a central processing unit (CPU), an application processor (AP), a graphic processing unit (GPU), a communication processor (CP), an image signal processor (ISP), and a controller.

The memory 10003 may store data information for the operation of the processor 10002 or the display module 10001. When the processor 10002 executes an application stored in the memory 10003, an image data signal and/or an input control signal may be transmitted to the display module 10001. The display module 10001 may process the received signal and output image information through a display screen.

The power module 10004 may include a power supply module such as a power adapter and a battery device, and a power conversion module that converts the power supplied by the power supply module to generate power for the operation of the electronic device 10000.

At least one of the elements of the electronic device 10000 described above may be included in the display devices according to the embodiments described above. In addition, some of the individual modules functioning as a single module may be included in the display device while some others may be provided separately from the display device. For example, the display device may include the display module 10001, and the processor 10002, the memory 10003 and the power module 10004 may be implemented as other devices inside the electronic device 10000 instead of the display device.

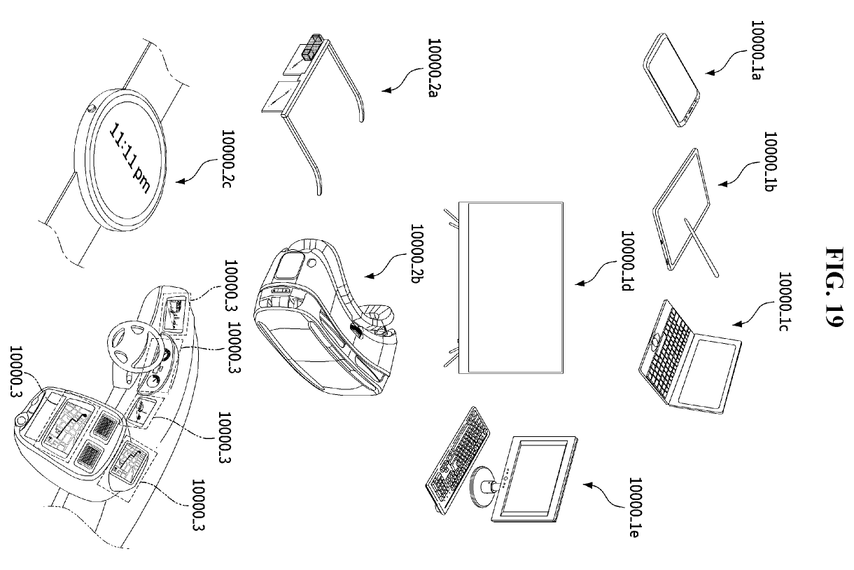

FIG. 19 is a view showing electronic devices according to a variety of embodiments of the present disclosure.

Referring to FIG. 19, a variety of electronic devices employing display devices according to embodiments may include not only image display electronic devices such as a smart phone 10000_1a, a tablet PC 10000_1b, a laptop computer 10000_1c, a TV 10000_1d and a desktop monitor 10000_1e, but also wearable electronic devices including display modules such as smart glasses 10000_2a, a head-mounted display 10000_2b and a smart watch 10000_2c, and electronic devices for vehicles 10000_3 including display modules such as a center information display (CID) placed on the dashboard, the center fascia and the dashboard of a vehicle, and a room mirror display.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a display module; and
a module support member placed under the display module,
wherein the module support member comprises:
a first support layer;
a second support layer placed under the first support layer; and
a plurality of supports arranged inside one of the first support layer and the second support layer.

2. The display device of claim 1, wherein the first support layer has a lower modulus than the second support layer.

3. The display device of claim 1, wherein the first support layer has a lower viscosity than the second support layer.

4. The display device of claim 1, wherein the supports are arranged inside the first support layer, and
wherein a thickness of the first support layer is larger than a thickness of the second support layer.

5. The display device of claim 4, wherein the thickness of the first support layer is at least three times the thickness of the second support layer, and
wherein a thickness of the supports is at least twice the thickness of the second support layer.

6. The display device of claim 4, wherein lower surfaces of the supports are in contact with an upper surface of the second support layer.

7. The display device of claim 1, wherein the supports are arranged inside the second support layer, and
wherein a thickness of the first support layer is smaller than a thickness of the second support layer.

8. The display device of claim 7, wherein the thickness of the second support layer is at least three times the thickness of the first support layer, and
wherein a thickness of the supports is at least twice the thickness of the first support layer.

9. The display device of claim 7, wherein upper surfaces of the supports are in contact with a lower surface of the first support layer.

10. The display device of claim 1, wherein the module support member further comprises:
a protective film located on the first support layer; and
a cover layer located on under the second support layer, and
wherein the protective film is in contact with the display module.

11. A method for fabricating a display device, the method comprising:
forming one of a first support layer and a second support layer;
arranging a plurality of supports on the one of the first support layer and the second support layer; and
forming the other of the first support layer and the second support layer on the one of the first support layer and the second support layer such that the plurality of supports is arranged inside the other of the first support layer and the second support layer.

12. The method of claim 11, wherein the forming of the one of the first support layer and the second support layer comprises: forming the second support layer, and
wherein the forming of the second support layer comprises: applying a second resin into a first cavity of a first jig and then thermally curing the second resin.

13. The method of claim 12, wherein the arranging of the plurality of supports on the one of the first support layer and the second support layer comprises: arranging the plurality of supports on the second support layer.

14. The method of claim 13, wherein the forming the other of the first support layer and the second support layer on the one of the first support layer and the second support layer such that the plurality of supports is arranged inside the other of the first support layer and the second support layer comprises: forming the first support layer on the second support layer such that the plurality of supports is arranged inside the first support layer, and
wherein the forming of the first support layer on the second support layer such that the plurality of supports is arranged inside the first support layer comprises:
placing a second jig having a protective film therein on the first jig;
injecting a first resin into a second cavity of the second jig; and
thermally curing the first resin.

15. The method of claim 11, wherein the forming of the one of the first support layer and the second support layer comprises: forming the first support layer, and
wherein the forming of the first support layer comprises:
placing a protective film on a first jig;
placing a first block on an edge of the protective film to form a first cavity; and
applying a first resin into the first cavity and then thermally curing the first resin.

16. The method of claim 15, wherein the arranging of the plurality of supports on the one of the first support layer and the second support layer comprises: arranging the plurality of supports on the first support layer.

17. The method of claim 16, wherein the forming of the other of the first support layer and the second support layer on the one of the first support layer and the second support layer such that the plurality of supports is arranged inside the other of the first support layer and the second support layer comprises: forming the second support layer on the first support layer such that the plurality of supports is arranged inside the second support layer, and
wherein the forming of the second support layer on the first support layer such that the plurality of supports is arranged inside the second support layer comprises:
placing a second block on the first block to form a second cavity;
applying a second resin into the second cavity; and
thermally curing the second resin.

18. The method of claim 11, further comprising:
placing a cover layer on the second support layer.

19. An electronic device comprising:
a display module; and
a module support member placed under the display module,
wherein the module support member comprises:
a first support layer;
a second support layer placed under the first support layer; and
a plurality of supports arranged inside one of the first support layer and the second support layer.

20. The electronic device of claim 19, further comprising: at least one of
a processor;
a memory in which data on at least one of the display module and the processor is stored; and
a power module, which supplies power to at least one of the display module, the processor and the memory.
